(19) United States
(12) Patent Application Publication
(10) Pub. No.: US 2014/0021557 A1
(43) Pub. Date: Jan. 23, 2014

(54) APPARATUS FOR FORWARD WELL BIAS IN A SEMICONDUCTOR INTEGRATED CIRCUIT

(71) Applicants: Michael Priel, Netanya (IL); Leonid Fleshel, Ashdod (IL); Anton Rozen, Gedera (IL); Dov Tzytkin, Ness Zyiona (IL)

(72) Inventors: Michael Priel, Netanya (IL); Leonid Fleshel, Ashdod (IL); Anton Rozen, Gedera (IL); Dov Tzytkin, Ness Zyiona (IL)

(73) Assignee: Freescale Semiconductor, Inc., Austin, TX (US)

(21) Appl. No.: 14/008,581

(22) PCT Filed: Mar. 30, 2011
(86) PCT No.: PCT/IB2011/051360

§ 371 Date: Sep. 30, 2013

(51) Int. Cl. H01L 27/06

(52) U.S. Cl. CPC H01L 27/0629
USPC 257/369

(57) ABSTRACT

There is provided a semiconductor Integrated Circuit device having forward well biasing, in which at least one protection device is connected between a supply voltage and a forward well bias voltage.

### FIELD OF THE INVENTION

This invention relates to semiconductor Integrated Circuits in general, and to Semiconductor integrated Circuits having forward well biasing in particular.

### BACKGROUND OF THE INVENTION

In recent years, there has been an explosion in the use of mobile computing devices, such as smart phones, personal navigation devices, tablets (and other small form factor general computing devices), portable entertainment devices, personal games machine and the like.

There are a number of factors driving the uptake of mobile devices, and these include: the increased availability of mobile communication network bandwidth at reasonable cost (through the rollout of comprehensive mobile data networks, such as 3G/4G, wireless WAN technology—e.g. WiMAX—and the like); increased battery energy density/capacity (especially due to the introduction and improvements in Lithium Ion type batteries); and improved Integrated Circuits (IC) having increased computational capabilities whilst consuming relatively less power.

To improve the computational capability of Integrated Circuits (both mobile and, indeed, non-mobile) increased operating frequencies are used, whilst power consumption is not increased, so that the resultant Integrated Circuit not only has sufficient processing power to carry out the increasingly demanding operations of a user (e.g. streaming moving video over high speed mobile data networks), but also at a power consumption level that allows sufficient length of use of the mobile device whilst it is operating on battery power alone. These improvements to Integrated Circuits not only impact their use in mobile devices, but also improves devices meant for fixed power supplies (i.e. “mains” power), as reduced power requirements of the Integrated Circuits leads to more efficient “mains” operated hardware (through such things as reduced absolute power requirement of the IC, and a corresponding reduction in the IC cooling requirements).

As the operating frequency of an Integrated Circuit increases, generally so too does the power consumption. This is partly due to switching and leakage currents.

Leakage currents increase as the Integrated Circuit process size shrinks (i.e. reduction in the minimum dimensions attainable for individual Integrated Circuit structures, often quoted in nanometres, e.g. 45 nm, 32 nm, 22 nm and below), because the physical reduction in the size of features on the Integrated Circuit can cause problems such as a reduction in the “electrical separation” between active portions of the Integrated Circuit. For example, the thicknesses of insulating (non-conducting) portions of the Integrated Circuit that isolate the conducting portions may be reduced, leading to an increased chance of leakage through said insulating portion. Furthermore, the chance of electron tunnelling also increases when process size shrinks occur.

A methodology to increase operating frequency of an Integrated Circuit whilst at least maintaining, if not lowering the leakage currents is to use forward well biasing. This technique involves applying a forward biasing voltage to the “well” within which an Integrated Circuit feature, such as transistor, is formed. The wells are there partly to isolate the different portions of the Integrated Circuit from the whole, and partly because applying the forward well bias reduces the threshold voltages for the transistors within the well (i.e. the voltage point where a signal is considered to go from a binary “1” to “0”, or vice versa). However, there are problems associated with the prior art forward well biasing techniques.

The prior art and its associated problems will be discussed in more detail later with reference to relevant drawings.

### SUMMARY OF THE INVENTION

The present invention provides a semiconductor Integrated Circuit device having forward well biasing, as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 schematically shows a cross-sectional view of a portion of an exemplary planar semiconductor Integrated Circuit device formed on a substrate having N and P type well regions;

FIG. 2 schematically shows a top down view of a larger portion of the exemplary planar semiconductor Integrated Circuit device of FIG. 1, including well tie cells;

FIG. 3 schematically shows in more detail an example of a well tie cell of FIG. 2;

FIG. 4 schematically shows a top down view of a larger portion of an example of a planar semiconductor Integrated Circuit device having well tie cells;

FIG. 5 schematically shows in more detail the example well tie cell of FIG. 4;

FIG. 6 shows a cross-sectional view of a portion of an exemplary planar semiconductor Integrated Circuit device formed on a substrate having N and P type well regions, with a schematic representation of how the forward well bias protection devices are coupled thereto;

FIG. 7 shows a fully schematic diagram version of the portion of the semiconductor Integrated Circuit of FIG. 6.

### DETAILED DESCRIPTION OF THE PREFERRED EMBODIMENTS

Because the illustrated embodiments of the present invention may for the most part be implemented using electronic components and circuits known to those skilled in the art, details will not be explained in any greater extent than that considered necessary for the understanding and appreciation of the underlying concepts of the present invention and in order not to obfuscate or distract from the teachings of the present invention.

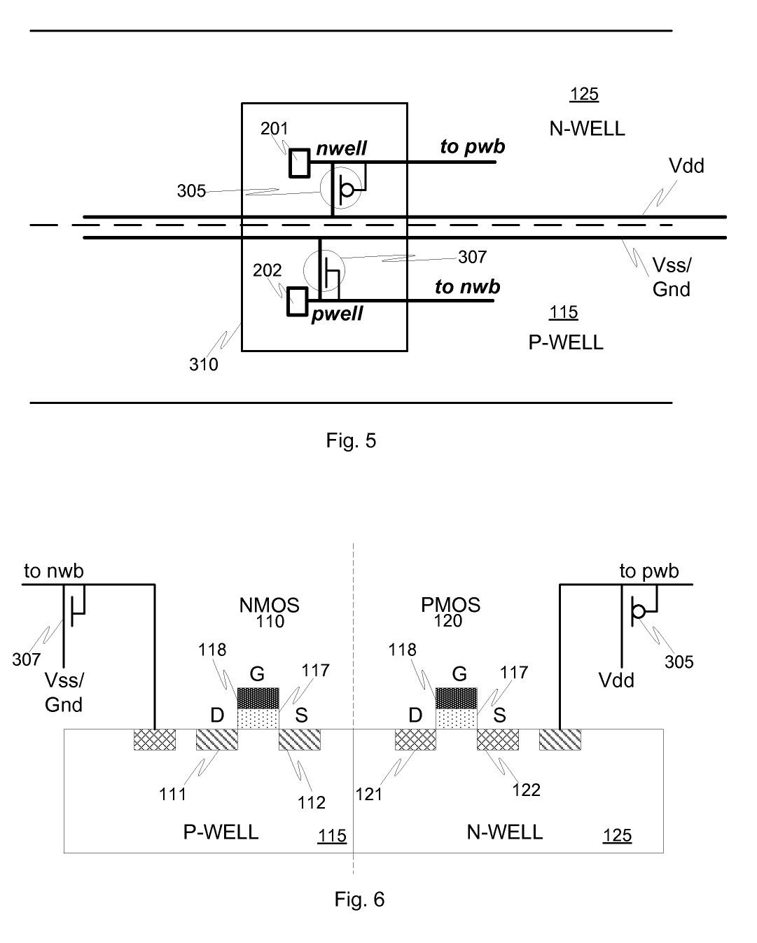

FIG. 5 shows an example of a portion of a semiconductor Integrated Circuit device having forward well biasing, in which at least one protection device 305, 307 is connected between a supply voltage Vdd, Vss, and a forward well bias voltage, pwb, nwb.

The semiconductor Integrated Circuit may be a CMOS device, and in this case the forward well bias voltage may comprise a PMOS forward well bias voltage, pwb, and a complimentary NMOS forward well bias, nwb.

The supply voltage may comprise a positive supply voltage (Vdd) and a negative supply voltage or ground (Vss), and as such, the at least one protection device may be formed from a protection device 305 coupled between the positive supply voltage (Vdd) and the PMOS forward well bias voltage, pwb, and/or a protection device 307 coupled between the negative supply voltage or ground (Vss) and the NMOS forward well bias voltage, nwb.

The at least one protection device, 305, 307, may be formed of at least one protection diode. More particularly, the at least one protection device may comprise at least one transistor arranged as a diode. When a transistor arranged as a diode is used, there may be greater control over the threshold voltage through suitable dimensioning of the transistor device.

In some examples, the protection diode coupled between the positive supply voltage (Vdd) and the PMOS forward well bias voltage, pwb, may comprise a PMOS transistor 305 arranged as a diode, and the protection diode coupled between the negative supply voltage or ground (Vss) and the NMOS forward well bias voltage, nwb, may comprise an NMOS transistor 307 arranged as a diode.

In some examples, the at least one protection device is comprised within a well tie cell connecting a well region of the semiconductor Integrated Circuit to a respective one of the forward well bias voltages.

The forward well bias voltage(s), pwb, nwb, may be independently provided by a dedicated forward well biasing circuit, or alternatively, may be generated by interaction of the protection device threshold voltage(s) and the supply voltage(s), Vdd, Vss.

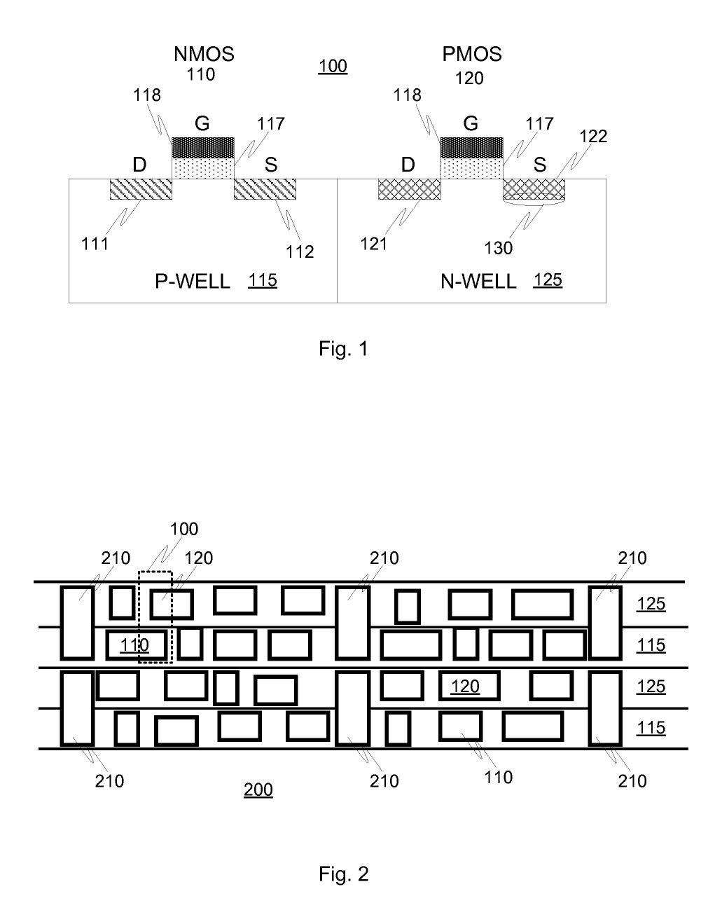

The protection device may have a threshold voltage arranged to be below a threshold voltage of any parasitic diode 130 formations in the semiconductor Integrated Circuit device, as shown in FIG. 1. An example may be where the protection device has a threshold voltage between 0.4 and 0.5V.

A benefit of using forward well biasing in an Integrated Circuit is that the switching thresholds of the transistors 110, 120 (or other devices) forming the Integrated Circuit may be reduced. This, in turn, allows the overall power supply (i.e. voltages used to supply power to the Integrated Circuit) for the Integrated Circuit to be reduced in voltage, so that the overall power consumption of the semiconductor Integrated Circuit device incorporating forward well biasing may be reduced.

Complementary Metal-Oxide-Semiconductor (CMOS) Integrated Circuits may be formed as planar devices on and in a substrate (such as silicon). The ‘complementary’ nature of these devices comes from the fact that a typical digital design style used in CMOS uses complementary and symmetrical pairs of p-type and n-type Metal-Oxide-Semiconductor Field Effect Transistors (MOSFETs) for logic functions, i.e. CMOS logic may incorporate transistors made from both conductivity types. Other types of transistors may also be used in a CMOS design, and the present invention is not necessarily limited to CMOS.

The active devices (i.e. individual transistors, and the like) of a CMOS Integrated Circuit are formed of a certain type (so called PMOS or NMOS type), within a well of opposing type (N-WELL or P-WELL). A ‘well’ may be a particular doping profile within the substrate. The type (P or N) of a well is based upon whether the primary charge carriers are electrons or “holes” (i.e. a lack of an electron, which is considered a positive charge carrier), and usually relates to the type of doping used on the respective portions of the substrate (e.g. via diffusion of a chosen dopant in to the base substrate). There are a number of well known dopants, for example Boron. The present invention is not limited to any particular dopant type. The level of doping used to get P or N type is reflected by the sign of the respective type, thus a P⁺ is more heavily doped than a P⁻, and it is similar for N⁺ and N⁻. The use of ‘types’, as summarised above, is well known in the art, so no further detailed explanation is provided here.

FIG. 1 schematically shows a cross-sectional view of a portion 100 of an example of a planar semiconductor Integrated Circuit device formed on and in a substrate having N and P type well regions. For clarity, the portion shown in FIG. 1 only comprises a single NMOS device 110 formed in a P type well (P-WELL 115) region, and a single PMOS device 120 formed in an N type well (N-WELL 125) region. The Integrated Circuit device can be formed in the substrate using planar construction techniques well known in the art—i.e. formed from the bottom up by successive steps of: deposition, etching, doping, patterning, and the like. The N or P type wells can be formed first, since the actual active devices must be formed within these regions, and they can be only lightly doped (i.e. using N⁻ and P⁻ type diffusion regions). For example, the well regions 115, 125 may be formed in an initial stage by providing a suitable dopant in a desired concentration. As shown, the well regions surround the respective devices 110, 120 and extend from the top surface of the substrate into the substrate to a depth, which may be less than or equal to the thickness of the substrate.

In the example shown, the NMOS device 110 comprises a Drain 111 and Source 112 formed of N⁺ diffusion material (i.e. using an N-type dopant to produced a highly N-doped region) formed within the P-WELL 115, with a Gate 118 formed of some kind of conductor (e.g. metal or polysilicon) formed over an insulating layer 117 (such as silicon oxide). The PMOS device 120 is similarly formed (but with inverted ‘type’) inside the N-WELL 125, in this case with Drain 121 and Source 122 formed of P⁺ diffusion regions (i.e. using a P-type dopant, at relatively high levels, higher than the P⁻ in the P-WELL). It will be noted that the Drain and Source contacts (of both type—items 111/112/121/122) form a parasitic diode with the respective well regions (P-WELL 115 or N-WELL 125), one of which is circled in FIG. 1—item 130. Depending on how the devices 110/120 are connected to the supply (Vdd/Vss), these parasitic diodes (e.g. 130) can cause unwanted currents, especially if forward biased.

In fully functional Integrated Circuits, the basic form of FIG. 1, or similar, is repeated many times. Accordingly, FIG. 2 schematically shows a top down view of a larger portion of an exemplary planar semiconductor Integrated Circuit device, including an indication of where the portion shown in FIG. 1 may be found, relative to the rest of the Integrated Circuit. It can be seen that there are rows of respective well type (P-WELL 115 or N-WELL 125), with well tie cells 210 connecting the respective well regions to well biasing circuitry (not shown) that supplies the respective PMOS and NMOS well biasing voltage(s).

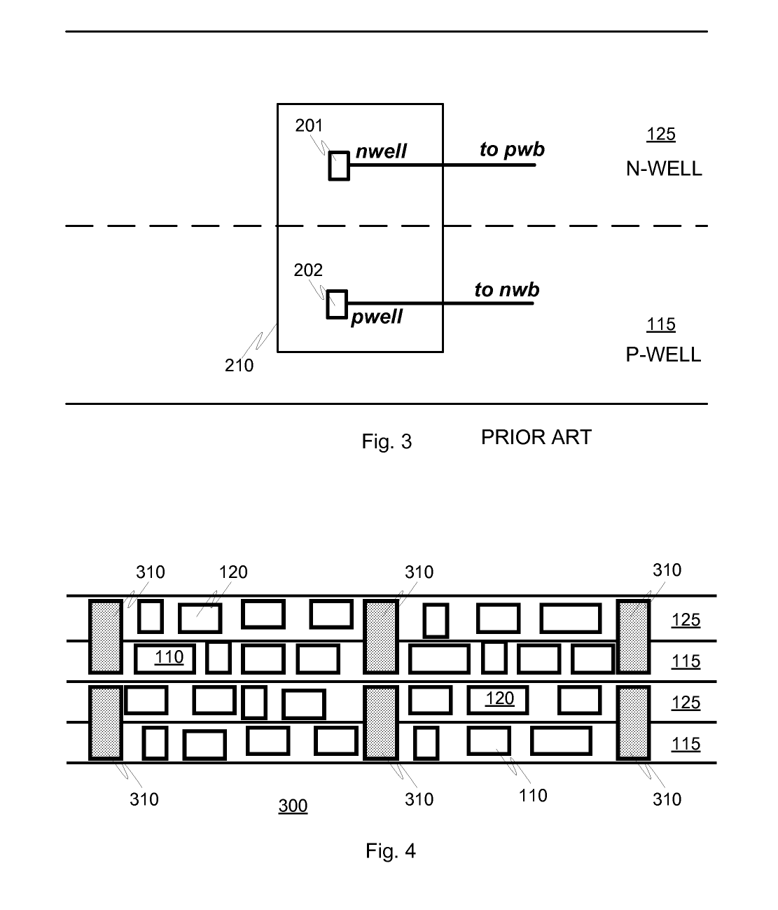

FIG. 3 schematically shows in more detail an example of a well tie cell of FIG. 2. The well tie cell comprises a connection pad 201 which provides a connection to the N-WELL region 125 through any layers above the region 125 and which can be connected to the PMOS well bias voltage (pwb). Similarly, there is a connection pad 202 which provides a connection through to the P-WELL region 115 through any layers above the region 115 and can be connected to the NMOS well bias voltage (nwb). The well tie cells 210 are simply tying the physically separated (but nominally the same type) well regions to the respective NMOS or PMOS well biasing voltages (pwb or nwb). This is done because, in order to achieve certain functionality, the (planar) layout of the overall Integrated Device will naturally mean well regions (P or N type) are isolated from one another, yet the regions of the same type (N-WELL or P-WELL) still need to electrically link to the same respective well bias voltage (pwb or nwb) supply.

A problem with using forward well bias, is the forward biased parasitic diode current resultant from the parasitic diode (e.g. item 130 in FIG. 1), which can cause possible latch-up conditions and increase overall power consumption of the semiconductor Integrated Circuit device. Latch-ups are, for example, faults in the operation of an Integrated Circuit, due to certain portions getting stuck in a certain state due to undesirable currents forming within the Integrated Circuit. In the example given, this may be the current flowing through the forward biased parasitic diode 130. Any currents flowing in an Integrated Circuit device, such as the forward biased parasitic diode current, add to the power consumption of the overall device. Since the forward biased parasitic diode current has no useful purpose (in fact, it has a detrimental effect by causing latch-up conditions), it is a pure waste of power in the semiconductor Integrated Circuit. Thus, it is particularly advantageous to reduce or remove the possibility for latch up, as it prevents both undesirable operation and reduces power consumption.

The forward biased parasitic current is strongly dependent on the biasing voltage value applied (nwb or pwb), hence it varies as the forward biasing voltages pwb/nwb fluctuate. Furthermore, from another side, due to weak power grid connection of the well tie cells to the special well biasing voltage supplies (pwb/nwb), inaccuracies in the generation of this well supply, and AC noise in the local well, control of the well bias voltages (pwb/nwb) is very problematic in the prior art. This is to say, it is hard to keep the respective well biasing voltage(s) constant.

As explained below in more detail, a protection device may be included into the Integrated Circuit device. The protection device can, for example, be a diode, such as a diode formed from a transistor connected as a diode to the respective well biasing supply (i.e. PMOS well bias, pwb, or NMOS well bias, nwb). The protection diode/transistor can have a threshold voltage slightly higher than the targeted respective well biasing voltages (pwb/nwb), but which is still, much, lower than the latch up/forward biased parasitic diode voltage condition. Using a transistor connected to operate as a diode is a particularly suitable way to achieve the desired characteristics, such as threshold voltage, because, for example, there are more controllable parameters (e.g. length/width/depth/separation of Source/Drain/Gate, etc) that can be controlled when forming a transistor using planar construction techniques, compared to a simple diode.

Since the variation of the protection diode/transistor threshold voltage operates in the same direction as the optimal bias voltage target, the inclusion of the protection device allows the adjustment of the bias voltage to a desired value, e.g. as determined by the specified Process Voltage Temperature (PVT) characteristics (i.e. desirable operational characteristics).

The proposed implementation may be used together with dedicated forward well biasing circuitry (providing separate specially regulated biasing voltage supplies, pwb and nwb, respectively). Alternatively, the required forward well bias voltage may be generated directly from the power supply using the protection device(s) (connected via an amplifier, if suitable). This provides a simple, yet fully functional solution to providing suitable forward well biasing voltage(s). The respective forward well biasing supplies may be provided through the interaction of the protection device threshold voltage with the respective supply voltage (Vdd and/or Vss), i.e. the protection device acts as a voltage clamp holding the respective forward well bias voltages (pwb/nwb) at a voltage equal to the protection device threshold voltage above or below the respective supply (Vdd and/or Vss).

FIG. 4 schematically shows a top down view of a larger portion of an example of a planar semiconductor Integrated Circuit device having well tie cells 310 incorporating protection devices according to an example of the present invention. The basic location of the well tie cells can, as shown, remain the same as in known devices, hence are easy to implement into existing Integrated Circuit design streams.

FIG. 5 schematically shows in more detail an example of the well tie cell 310 of FIG. 4. The protection diode (in the drawings, an NMOS or PMOS transistor connected in simple diode formation is shown, i.e. with the gate and one drain/source connected together) is connected between the Integrated Circuit supply voltages (Vdd/Vss) and the suitable type well bias voltage, pwb or nwb. The connection to the connection pads 201 and 202 are not changed compared to the example of FIG. 3. In more detail, the pwb can be connected to the positive supply, Vdd, by a PMOS transistor 305, whilst the nwb can be connected to the ground/negative supply, Vss, by a NMOS transistor 307. The type of transistor 305 and 307 used matches/reflects the type of transistor in the well region being forward biased.

FIG. 6 schematically shows a cross-sectional view of a portion of an example of a planar semiconductor Integrated Circuit device formed on a substrate having N and P type well regions, including a schematic representation of how the forward well bias protection devices are arranged. In the specific example shown, the proposed protection transistor devices 305 and 307 are connected to the wells (P-WELL 115 and N-WELL 125) by regions 601, 602 of doping of the same type as the well, but with a higher doping concentration. Thus, where the well is P-type well (115), the connection region 601 is P⁺ type and where the well is N-type well (125), connection region 602 is N⁺ type. Regions 601/602 can improve performance by improving conductivity at the connection point. It will be apparent that the device may also be implemented without such regions.

In the above described way, the PMOS and NMOS well bias voltages (pwb/nwb) are coupled to the respective power supply (Vdd/Vss), but offset by the protection device threshold voltage. By forming the protection devices accurately, and with the correct level of threshold voltage, the correct level of PMOS/NMOS well bias voltage may be supplied consistently, accurately, simply and without major divergence from the power supply—i.e. it reduces the variability of the forward well bias voltages with respect to the power supply.

The previously mentioned parasitic diode 130 may typically have a threshold voltage in the range of 0.7 to 0.8 volts. Whereas, the purposefully added protection diode/transistor(s) may be formed to have a lower threshold voltage than the threshold voltage of the parasitic diode, typically in the region of 0.4 to 0.5V. Thus, not only are the resultant currents reduced (thereby improving power efficiency of the overall semiconductor Integrated Circuit), but also the purposefully included protection diode/transistor(s) typically turn on first (because they have a lower threshold voltage), thereby preventing the parasitic diodes from turning on, hence removing the latch up problems associated with the parasitic diodes 130.

It will be appreciated that the teachings herein are not limited to only the specific formations described, but are equally applicable to all forward well biased Integrated Circuit formations. For example, whilst transistors having a gate insulation layer 117 are shown, the transistors may equally be transistors not having gate insulating layers. Also, the above has been described in terms of the well tie cells containing the protection diode/transistor formed between the PMOS well bias voltage (pwb) and positive power supply (Vdd), and another protection diode/transistor formed between the NMOS well bias voltage (nwb) and negative/ground power supply (Vss). Implementation of these protection diode/transistor(s) into the well tie cell is a simple and effective solution, especially when using computer aided circuit design using standardised functional blocks, since the well tie cell including the afore-described protection diode/transistor(s) may become a new type of standard function block. However, it will be appreciated that the two protection diode/transistor(s) may be formed at any other suitable location where they can function in the same way instead (i.e. not within the well tie cell).

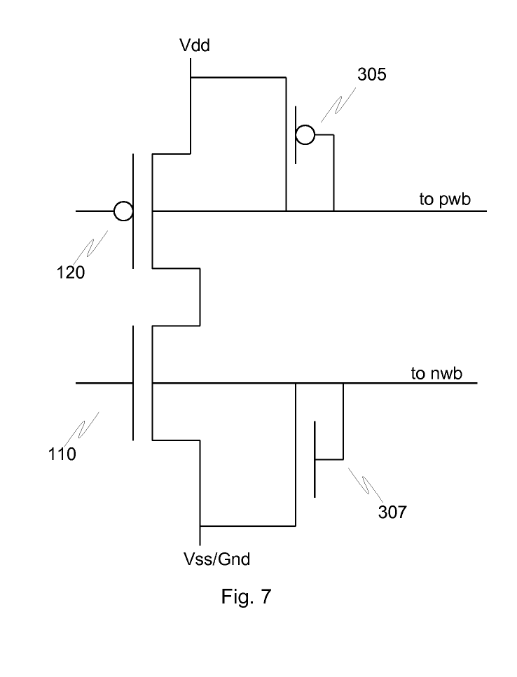

FIG. 7 shows an alternative, fully schematic, diagram of the equivalent circuit representation of the portion of the semiconductor Integrated Circuit of FIG. 6, for clarity of understanding. The same numerals are used to represent the same features. As shown, transistors 110, 120 are connected in series between Vdd and Vss. Transistors 306, 307 connecting the wells to Vdd and Vss respectively. Each well is further connected to a respective bias pwb, nwb.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor Integrated Circuit device may be formed from a substrate which may be any suitable semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under”, “lower” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. For example, the location of the protection device may be varied.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A semiconductor Integrated Circuit device having forward well biasing, comprising:
at least one protection device connected between a supply voltage and a forward well bias voltage.

2. The semiconductor Integrated Circuit device of claim 1, wherein the semiconductor Integrated Circuit device is a CMOS device, and the forward well bias voltage comprises a PMOS forward well bias voltage and a complimentary NMOS forward well bias.

3. The semiconductor Integrated Circuit device of claim 2, wherein
the supply voltage comprises a positive supply voltage and a negative supply voltage or ground; and
the at least one protection device comprises one or more of:
a protection device coupled between the positive supply voltage and the PMOS forward well bias voltage, and
a protection device coupled between the negative supply voltage or ground and the NMOS forward well bias voltage.

4. The semiconductor Integrated Circuit device of claim 3, wherein the at least one protection device comprises at least one protection diode.

5. The semiconductor Integrated Circuit device of claim 3, wherein the at least one protection device comprises at least one transistor arranged as a diode.

6. The semiconductor Integrated Circuit device of claim 4, wherein:
the protection diode coupled between the positive supply voltage and the PMOS forward well bias voltage comprises a PMOS transistor arranged as a diode, or
the protection diode coupled between the negative supply voltage or ground and the NMOS forward well bias voltage comprises an NMOS transistor arranged as a diode.

7. The semiconductor Integrated Circuit device of claim 1, wherein the at least one protection device is comprised within a well tie cell connecting a well region of the semiconductor Integrated Circuit to a respective forward well bias voltage.

8. The semiconductor Integrated Circuit device of claim 7, wherein the forward well bias voltage is independently provided by a dedicated forward well biasing circuit.

9. The semiconductor Integrated Circuit device of claim 7, wherein the forward well biasing voltage is generated by interaction of a protection device threshold voltage and the supply voltage.

10. The semiconductor Integrated Circuit device of claim 1, wherein the protection device has a threshold voltage arranged to be below a threshold voltage of any parasitic diode formation in the semiconductor Integrated Circuit device.

11. The semiconductor Integrated Circuit device of claim 10, wherein the protection device has a threshold voltage between 0.4 and 0.5V.
